(19) United States
(12) Patent Application Publication
(10) Pub. No.: US 2018/0151629 A1
(43) Pub. Date: May 31, 2018

(54) OLED ELEMENT, OLED DEVICE, AND OLED DISPLAY DEVICE

(71) Applicant: BOE Technology Group Co., Ltd., Beijing (CN)

(72) Inventors: Chang Yen Wu, Beijing (CN); Chinlung Liao, Beijing (CN); Shoulei Shi, Beijing (CN)

(21) Appl. No.: 15/720,712

(22) Filed: Sep. 29, 2017

(30) Foreign Application Priority Data
Nov. 30, 2016 (CN) 201611094964.2

(51) Int. Cl. H01L 27/32; H01L 51/52

(52) U.S. Cl. CPC H01L 27/3209; G09G 2300/0452; H01L 51/5203

(57) ABSTRACT

The disclosure relates to an OLED element, an OLED device, and an OLED display device. An OLED element includes: at least two light emitting elements stacked, wherein at least one light emitting element includes light emitting layers in at least two colors, and coverage areas of positive projections of the light emitting layers in the different light emitting elements onto either surface of the OLED element at most partially overlap with each other. The colors from the light emitting layers in the different colors arranged in the same light emitting element can be mixed with the colors from the light emitting layers in the other light emitting elements, and the mixed colors can be further adjusted to the desirable color.

### CROSS-REFERENCES TO RELATED APPLICATIONS

This application claims priority to Chinese patent application No. 201611094964.2 filed on Nov. 30, 2016, which is incorporated herein by reference in its entirety.

### FIELD

The present disclosure relates to the field of display technologies, and particularly to an OLED element, an OLED device, and an OLED display device.

### BACKGROUND

In the prior art, white light can be produced on an OLED panel by mixing RGB (Red, Green, Blue) colors at each pixel element, or by mixing other colors.

However in order to mixture the colors at any display element on an existing series OLED panel, different layers of the display element can be arranged in different colors for their mixing.

### SUMMARY

An OLED element includes: at least two light emitting elements stacked, wherein at least one light emitting element comprises light emitting layers in at least two colors, and coverage areas of positive projections of the light emitting layers in the different light emitting elements onto either surface of the OLED element at most partially overlap with each other.

An OLED device includes a plurality of the OLED elements above.

An OLED display includes the OLED device above.

### BRIEF DESCRIPTION OF THE DRAWINGS

In order to make the technical solutions in the embodiments of the disclosure more apparent, the drawings to be used in a description of the embodiments will be briefly introduced below, and apparently the drawings to be described below are merely illustrative of some embodiments of the disclosure, and those ordinarily skilled in the art can derive from these drawings other drawings without any inventive effort. In the drawings:

FIG. 1 is a schematic structural diagram of an OLED element in the related art;

FIG. 2 is a first schematic structural diagram of an OLED element in accordance with an embodiment of the disclosure;

FIG. 3 is a second schematic structural diagram of an OLED element in accordance with an embodiment of the disclosure;

FIG. 4A to FIG. 4C are schematic structural diagrams respectively of OLED elements in a first example to a third example of the disclosure;

FIG. 5A is a schematic structural diagram of an OLED device in accordance with an embodiment of the disclosure in a top view; and

FIG. 5B is a schematic structural diagram of an OLED device in accordance with an embodiment of the disclosure in a sectional view.

### DETAILED DESCRIPTION OF THE EMBODIMENTS

In order to make the objects, the technical solutions, and the advantages of the disclosure more apparent, the disclosure will be further described in details with reference to the drawings. Apparently the described embodiments are only a part but all of the embodiments of the disclosure. Based upon the embodiments here of the disclosure, all of other embodiments derived by those ordinarily skilled in the art without any inventive effort shall come into the scope of the disclosure.

The technical solution according to the disclosure will be described below in details in connection with embodiments thereof, and the disclosure will include the following embodiments without any limitation thereto.

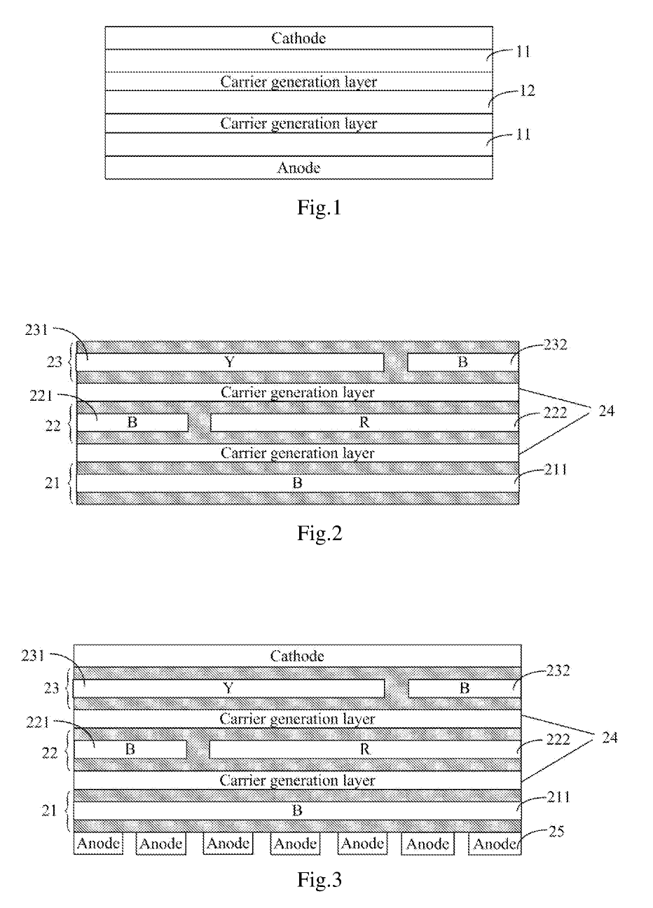

In some embodiment, an OLED element as illustrated in FIG. 1 includes two fluorescent blue light emitting elements 11, and a phosphorescent yellow light emitting element 12 arranged between the two fluorescent blue light emitting elements 11. In order to produce cold white light, it needs to degrade the light emission efficiency of the phosphorescent yellow light to mix into the desired cold white light.

An embodiment of the disclosure provides an OLED element generally including:

At least two light emitting elements stacked, where at least one light emitting element includes light emitting layers in at least two colors, and coverage areas of positive projections of the light emitting layers in different light emitting elements onto either surface of the OLED element at most partially overlap with each other.

Specifically taking an OLED element as illustrated in FIG. 2 as an example, the OLED element includes a first light emitting element 21, a second light emitting element 22, and a third light emitting element 23, stacked successively between an anode to a cathode, where the first light emitting element 21 includes only one light emitting layer 211 displaying in blue and covering the entire display element; the second light emitting element 22 includes two light emitting layers including a light emitting layer 221 and a light emitting layer 222 respectively, where the light emitting layer 221 displays in blue, and the light emitting layer 222 displays in red; and the third light emitting element 23 includes two light emitting layers including a light emitting layer 231 and a light emitting layer 232 respectively, where the light emitting layer 231 displays in yellow, and the light emitting layer 232 displaying in blue. Each light emitting element includes an electron injection layer, an electron transport layer, a hole transport layer, and a hole injection layer (as represented as grids in the FIG. 2 of the disclosure), where the light emitting layers are located between the electron transport layer and the hole transport layer.

Furthermore the OLED element further includes carrier generation layers 24 connected with the adjacent light emitting elements.

In some embodiments, coverage areas of positive projections of the light emitting layers in different light emitting elements onto either surface of the OLED element at most partially overlap with each other, which refers to: the positive projection of all light emitting layers in one emitting element onto either surface of the OLED element, at most partially overlaps with the positive projection of all light emitting layers in another emitting element onto the surface of the OLED element.

In some embodiments, as illustrated in FIG. 2, in each light emitting element which includes the light emitting layers in at least two colors, the light emitting layers in the at least two colors are arranged at the same layer in the horizontal direction so that different color light is emitted in different areas of the light emitting element.

Furthermore there are different sizes of the light emitting layers in the same light emitting element so that each light emitting element can produce a larger number of colors as a result of mixing. When a light emitting layer in the same color is arranged at a layer throughout a light emitting element, and given a number of stacked layers, a desirable color has to be produced as a result of mixing in the OLED element at the expense of degrading the light emission efficiency of a light emitting layer in some light emitting element. Although the colors can be mixed in this color mixing scheme, the light emission efficiency of the light emitting layer may be underutilized. In the embodiment of the disclosure, at least one layer of light emitting element includes light emitting layers in at least two colors, and coverage areas of positive projections of the light emitting layers in the different light emitting elements onto either surface of the OLED element at most partially overlap with each other, so that the colors from the light emitting layers in the different colors in the same light emitting element can be mixed with the colors from the light emitting layers in the other light emitting elements, and the mixed colors can be further adjusted to the desirable color of light to be emitted. In this scheme, the colors can be mixed into the optimum color while guaranteeing the highest light emission efficiency of each light emitting layer.

In some embodiments, as illustrated in FIG. 2, the coverage areas of the positive projections of the light emitting layers in the different light emitting elements onto either surface of the OLED element different from each other so that the OLED element produces a number of different colors a result of mixing.

In some embodiments, as illustrated in FIG. 3, based on the embodiments according to FIG. 2, the OLED element further includes: electrode patterns 25 located on either surface of the OLED element, where on one hand, the electrode patterns 25 act as anodes, and a cathode is arranged on the other surface of the OLED element; and on the other hand, when the OLED element is a display element, then the electrode patterns 25 may act as a pixel definition layer to define each pixel structure in the display element.

As illustrated in FIG. 3, in the light emitting element including the light emitting layers in the at least two colors, a positive projection of a gap between every two adjacent light emitting layers onto either surface of the OLED element lies at a gap between the electrode patterns, so that the color mixing scheme in the OLED element may be adjusted to an integer multiple of pixel elements or other like elements to thereby improve in effect the regularity of mixing the colors so as to make the colors mixed more uniformly. Also in this scheme, since mixing of the colors may not be improved due to a too short distance between the adjacent light emitting layers, the distance between the light emitting layers can be shortened as many as possible to thereby save a material of the light emitting layers.

In the embodiment of the disclosure, the colors can be mixed in the OLED element in a number of modes, specific examples of which will be described below.

In a first example, all the gaps between the light emitting layers in one light emitting elements including the light emitting layers in the at least two colors overlap with all the gaps between the light emitting layers in another light emitting elements.

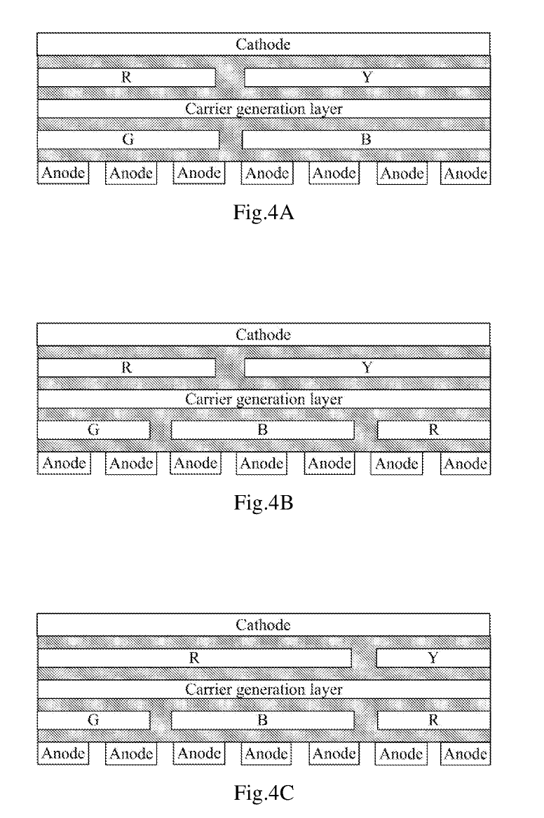

As illustrated in FIG. 4A, taking two light emitting elements stacked as an example, the light emitting layers in the light emitting element at the bottom layer include a green light emitting layer G and a blue light emitting layer B, and the light emitting layers in the light emitting element at the top layer are a red light emitting layer R and a yellow light emitting layer Y; and the size of the green light emitting layer G is the same as that of the red light emitting layer R, the size of the blue light emitting layer B is the same as that of the yellow light emitting Y, and the gap between the green light emitting layer G and the yellow light emitting layer Y overlaps with the gap between the red light emitting layer R and the yellow light emitting layer Y.

In this structure, the primary colors to be mixed can be determined according to the number of light emitting layers in each light emitting element, for example, when the red light emitting layer and the green light emitting layer are mixed into a color A, and the yellow light emitting layer and the blue light emitting layer are mixed into a color B, then the color A and the color B may be mixed into a desirable color C. Actually the specific primary colors to be mixed into the which color can be determined according to the number of light emitting layers in the light emitting element, and then mixed in effect into the desirable color without degrading the light emission efficiency of the light emitting layers.

In a second example, all the gaps between the light emitting layers in one light emitting element including the light emitting layers in the at least two colors do not overlap with all the gaps between the light emitting layers in another light emitting element.

As illustrated in FIG. 4B, taking two light emitting elements stacked as an example, the light emitting layers in the light emitting element at the bottom layer include a green light emitting layer G, a blue light emitting layer B, and a red light emitting layer R, and the light emitting layers in the light emitting element at the top layer are a red light emitting layer R and a yellow light emitting layer Y; and the gap between the red light emitting layer R and the yellow light emitting layer Y at the top layer does not overlap with any one gap at the bottom layer.

In this structure, although there are two light emitting layers arranged in the light emitting element at the top layer, the gap at the top layer does not overlap with any one gap at the bottom layer, so that there are light emitting areas in five different colors after the light emitting layers at the top layer are mixed with those at the bottom layer, to thereby improve the adjustability of the colors to be mixed so as to provide a larger number of combinations of colors to be mixed.

In a third example, a part of the gaps between the light emitting layers in one light emitting element including the light emitting layers in the at least two colors overlap with a part of the gaps between the light emitting layers in another emitting element.

As illustrated in FIG. 4C, taking two light emitting elements stacked as an example, the light emitting layers in the light emitting element at the bottom layer include a green light emitting layer G, a blue light emitting layer B, and a red light emitting layer R, and the light emitting layers in the light emitting element at the top layer are a red light emitting layer R and a yellow light emitting layer Y; and the gap between the red light emitting layer R and the yellow light emitting layer Y at the top layer overlaps with the gap between the blue light emitting layer B and the red light emitting layer R at the bottom layer, and the gap between the green light emitting layer G and the blue light emitting layer B at the bottom layer does not overlap with the gap at the top layer.

In this structure, a larger number of combinations of colors to be mixed as desirable can be provided despite a small number of light emitting layers in use, for example, the red light emitting layer R at the top layer, and the green light emitting layer G and the blue light emitting layer B at the bottom layer can be mixed into two primary colors to be mixed, to thereby save the material of the light emitting layers in that the colors can be mixed in effect using the light emitting layers in a smaller number of colors.

It shall be noted that there may be a number of schemes for mixing the colors in each OLED element according to the embodiment of the disclosure although they will not be enumerated here, and the number of light emitting elements stacked in each OLED element may alternatively be three or more although there are arranged two stacked light emitting elements in the embodiment of the disclosure.

In some the embodiments of the disclosure, the colors of the light emitting layers may be any one of red, blue, green, or yellow, or may be purple, azury, fluorescent green, fluorescent yellow, etc., although they will not be enumerated here.

Alike an embodiment of the disclosure further provides an OLED device including a plurality of the OLED elements according to any one of the embodiments above of the disclosure.

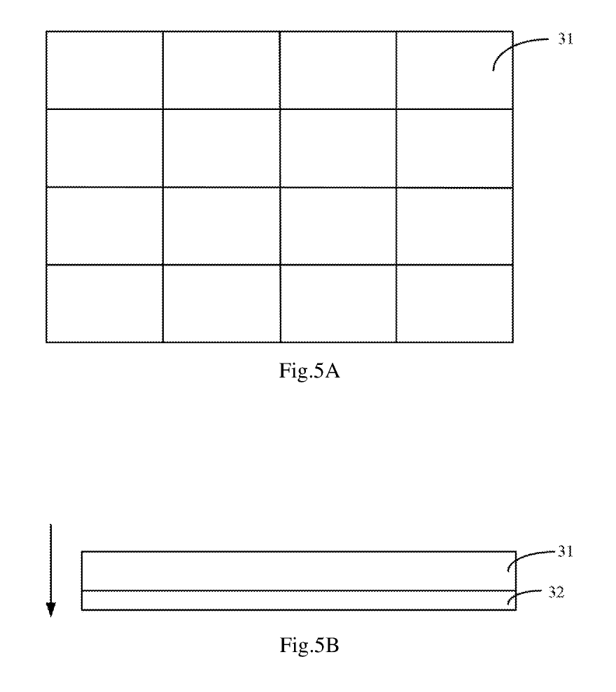

In some embodiments, taking what as illustrated in FIG. 5A as an example, the plurality of OLED elements 31 are arranged periodically in a matrix.

Furthermore in the sectional view as illustrated in FIG. 5B, the OLED device can further include a scattering plate 32 arranged at the light exit side of the plurality of OLED elements 31 to improve the effect of mixing the colors.

Furthermore an embodiment of the disclosure further provides an OLED display device including the OLED device according to the embodiment above of the disclosure, where the display device can be a mobile phone, a tablet computer, a TV set, a display, a notebook computer, a digital photo frame, a navigator, or any other product or component capable of displaying. All the other components indispensable to the display device can be appreciated by those ordinarily skilled in the art, so a repeated description thereof will be omitted here, and the embodiments of the disclosure will not be limited thereto.

Although the preferred embodiments of the disclosure have been described, those skilled in the art benefiting from the underlying inventive concept can make additional modifications and variations to these embodiments. Therefore the appended claims are intended to be construed as encompassing the preferred embodiments and all the modifications and variations coming into the scope of the disclosure.

Evidently those skilled in the art can make various modifications and variations to the disclosure without departing from the spirit and scope of the disclosure. Thus the disclosure is also intended to encompass these modifications and variations thereto so long as the modifications and variations come into the scope of the claims appended to the disclosure and their equivalents.

1. An Organic Light-Emitting Diode (OLED) element, comprising:
at least two light emitting elements stacked, wherein at least one light emitting element comprises light emitting layers in at least two colors, and coverage areas of positive projections of the light emitting layers in the different light emitting elements onto either surface of the OLED element at most partially overlap with each other.

2. The OLED element according to claim 1, wherein the light emitting layers in the at least two colors in the at least one light emitting element are arranged at the same layer in a horizontal direction.

3. The OLED element according to claim 2, wherein the light emitting layers in a same light emitting element have different sizes.

4. The OLED element according to claim 1, wherein the coverage areas of the positive projections of the light emitting layers in the different light emitting elements onto either surface of the OLED element different from each other.

5. The OLED element according to claim 1, further comprising: electrode patterns located on either surface of the OLED element, wherein:
in the light emitting element comprising the light emitting layers in the at least two colors, a positive projection of a gap between every two adjacent light emitting layers onto either surface of the OLED element lies at a gap between the electrode patterns.

6. The OLED element according to claim 1, wherein the colors of the light emitting layers comprise at least red, blue, green, or yellow.

7. The OLED element according to claim 2, further comprising: electrode patterns located on either surface of the OLED element, wherein:
in the light emitting element comprising the light emitting layers in the at least two colors, a positive projection of a gap between every two adjacent light emitting layers onto either surface of the OLED element lies at a gap between the electrode patterns.

8. The OLED element according to claim 3, further comprising: electrode patterns located on either surface of the OLED element, wherein:
in the light emitting element comprising the light emitting layers in the at least two colors, a positive projection of a gap between every two adjacent light emitting layers onto either surface of the OLED element lies at a gap between the electrode patterns.

9. The OLED element according to claim 4, further comprising: electrode patterns located on either surface of the OLED element, wherein:
in the light emitting element comprising the light emitting layers in the at least two colors, a positive projection of a gap between every two adjacent light emitting layers onto either surface of the OLED element lies at a gap between the electrode patterns.

10. The OLED element according to claim 2, wherein the colors of the light emitting layers comprise at least red, blue, green, or yellow.

11. The OLED element according to claim 3, wherein the colors of the light emitting layers comprise at least red, blue, green, or yellow.

12. The OLED element according to claim 4, wherein the colors of the light emitting layers comprise at least red, blue, green, or yellow.

13. An Organic Light-Emitting Diode (OLED) device, comprising a plurality of OLED elements, wherein each of the OLED elements comprises:
at least two light emitting elements stacked, wherein at least one light emitting element comprises light emitting layers in at least two colors, and coverage areas of positive projections of the light emitting layers in the different light emitting elements onto either surface of the OLED element at most partially overlap with each other.

14. The OLED device according to claim 13, wherein the plurality of OLED elements are arranged in a matrix.

15. The OLED device according to claim 13, further comprising: a scattering plate arranged at a light exit side of the plurality of OLED elements.

16. An Organic Light-Emitting Diode (OLED) display device, comprising an OLED device, wherein the OLED device comprises a plurality of OLED elements, and each of the OLED elements comprises:
at least two light emitting elements stacked, wherein at least one light emitting element comprises light emitting layers in at least two colors, and coverage areas of positive projections of the light emitting layers in the different light emitting elements onto either surface of the OLED element at most partially overlap with each other.
